(19) United States
(12) Patent Application Publication
(10) Pub. No.: US 2011/0241135 A1
(43) Pub. Date: Oct. 6, 2011

(54) MEMS ELEMENT

(75) Inventors: Yoshihiko Kurui, Kanagawa-ken (JP); Yoshiaki Shimooka, Tokyo (JP); Hiroaki Yamazaki, Kanagawa-ken (JP); Akihiro Kojima, Kanagawa-ken (JP)

(73) Assignee: KABUSHIKI KAISHA TOSHIBA, Tokyo (JP)

(21) Appl. No.: 13/050,083

(22) Filed: Mar. 17, 2011

(30) Foreign Application Priority Data
Apr. 2, 2010 (JP) 2010-86049

(51) Int. Cl. H01L 29/84

(52) U.S. Cl. 257/415; 257/E29.324

(57) ABSTRACT

According to an embodiment of the present invention, a MEMS element includes: a semiconductor substrate; an island insulating layer formed on the substrate, the insulating layer including an air gap layer having an air gap group, the air gap group including a plurality of air gaps disposed in an in-plane direction; and a MEMS capacitor formed above the air gap group on the insulating layer.

### CROSS-REFERENCE TO RELATED APPLICATION

This application is based upon and claims the benefit of priority from prior Japanese Patent Application No. 2010-86049, filed on Apr. 2, 2010, the entire contents of which are incorporated herein by reference.

### FIELD

Embodiments of the present invention relates to a MEMS element.

### BACKGROUND

Conventionally, a device in which a Micro Electro Mechanical System (MEMS) capacitor is provided on a semiconductor substrate with an insulating film interposed therebetween is known as a device including the MEMS capacitor. In such devices, a parasitic capacitance generated between the MEMS capacitor and the semiconductor substrate can be reduced by providing an insulating layer.

There is also disclosed a configuration in which a hollow portion is provided in the insulating layer. Because a dielectric constant of air is lower than that of the insulating layer, the parasitic capacitance can further be reduced by providing the hollow portion.

However, when the hollow portion is provided to an extent that the parasitic capacitance can sufficiently be reduced, possibly a mechanical strength of the insulating layer decreases to adversely affect reliability of the MEMS capacitor.

### BRIEF DESCRIPTION OF THE DRAWINGS

FIG. 1 is a top view illustrating a MEMS element according to an embodiment of the present invention;

FIG. 2 is a vertical sectional view of the MEMS element taken on a line II-II of FIG. 1;

FIGS. 3A and 3B are top views schematically illustrating dispositions of air gap groups when the air gap groups have quadrangular lattice (square lattice) patterns;

FIGS. 4A to 4C are top views schematically illustrating dispositions of air gap groups when the air gap groups have triangular lattice (hexagonal lattice) patterns; and

FIGS. 5A to 5J are sectional views illustrating a process of manufacturing the MEMS element of the embodiment.

### DETAILED DESCRIPTION

According to an embodiment of the invention, a MEMS element includes: a substrate; an island insulating layer formed on the substrate, the insulating layer including an air gap layer having an air gap group, the air gap group including a plurality of air gaps disposed in an in-plane direction; and a MEMS capacitor formed above the air gap group on the insulating layer.

### Embodiment

### (Configuration of MEMS Element)

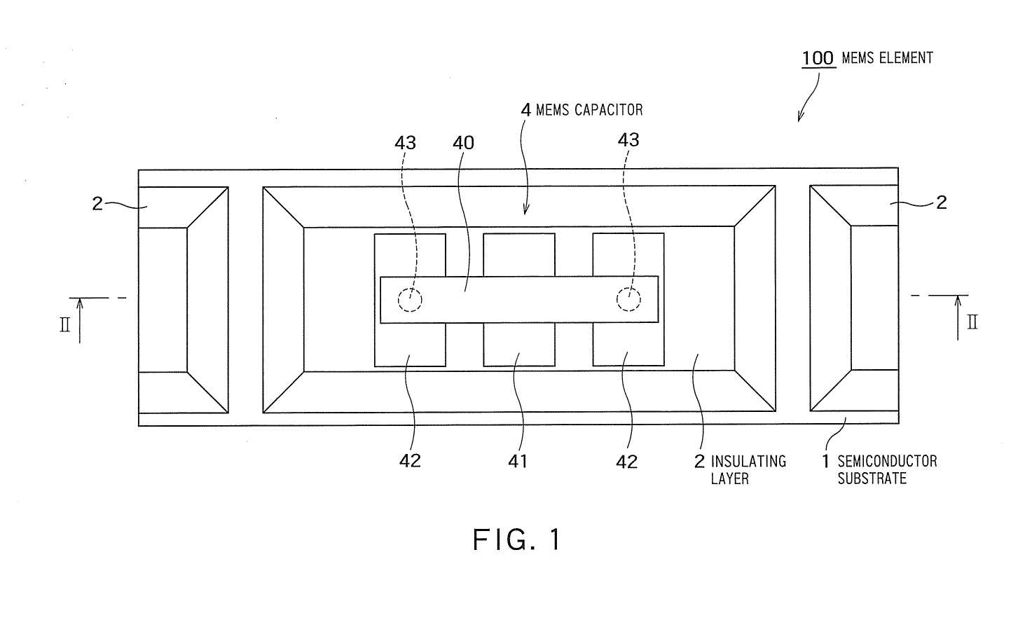

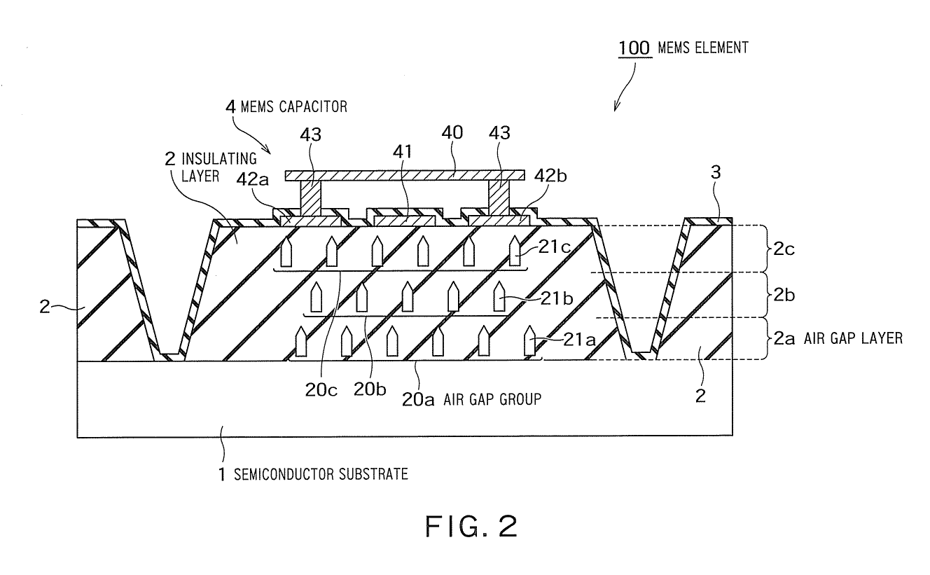

FIG. 1 is a plan view illustrating a MEMS element 100 according to an embodiment of the invention. FIG. 2 is a vertical sectional view of the MEMS element 100 taken on a line II-II of FIG. 1.

The MEMS element 100 includes a semiconductor substrate 1, an island insulating layer 2 that is formed on the semiconductor substrate 1, an insulating film 3 with which a surface of the insulating layer 2 is covered, and a MEMS capacitor 4 that is formed on the insulating layer 2.

The insulating layer 2 includes an air gap group including plural air gaps disposed in an in-plane direction. Referring to FIG. 2, the insulating layer 2 includes three layers, that is, an air gap layer 2a having an air gap group 20a including plural air gaps 21a, an air gap layer 2b having an air gap group 20b including plural air gaps 21b, and an air gap layer 2c having an air gap group 20c including plural air gaps 21c. The number of air gap layers is not limited to three. For example, only one air gap layer may be used.

A parasitic capacitance generated between the MEMS capacitor 4 and the semiconductor substrate 1 can be reduced by providing the insulating layer 2 between the semiconductor substrate 1 and the MEMS capacitor 4. Because a dielectric constant of air is lower than that of the insulating layer 2, the parasitic capacitance can further be reduced by providing the air gap groups 20a, 20b, and 20c in the insulating layer 2.

When such air gap group as the air gap groups 20a, 20b, and 20c including the plural air gaps that are independently disposed in the in-plane direction is formed, a decrease in mechanical strength of the insulating layer 2 can be suppressed compared with the formation of one large air gap.

Compared with the formation of the vertically long air gap single layer, the decrease in mechanical strength can more effectively be suppressed by forming such air gap multi layer as the air gap layers 2a, 2b, and 2c. Because the air gaps can be formed in a wide range in a thickness direction of the insulating layer 2 without increasing an aspect ratio compared with the formation of the vertically long air gap single layer, patterning of the insulating layer 2 is easily performed in order to form the air gap.

The MEMS capacitor 4 is formed above the air gap groups 20a, 20b, and 20c of the insulating layer 2. The air gap groups 20a, 20b, and 20c may be formed in a region except the region below the MEMS capacitor 4. However, the parasitic capacitance is sufficiently reduced when the air gap groups 20a, 20b, and 20c are formed only below the MEMS capacitor 4. Preferably, the air gap groups 20a, 20b, and 20c are formed only below the MEMS capacitor 4 in order to secure the mechanical strength of the insulating layer 2.

The MEMS capacitor 4 includes a signal line 41 that is a lower electrode, ground lines 42a and 42b that are connected to GND, support portions 43a and 43b that are formed on the ground lines 42a and 42b, respectively, and a bridge 40 that is an upper electrode bridging the support portions 43a and 43b. When a voltage is applied between the bridge 40 and the signal line 41, the bridge 40 is deformed to change a gap between the bridge 40 and the signal line 41, thereby changing an electric capacitance. A MEMS capacitor having a structure different from that of the MEMS capacitor 4 may be used.

A parameter called a Q value is used as one of indexes of a capacitor characteristic. The Q value is expressed by an equation of Q=1/(ωCR). The Q value shows that the capacitor characteristic becomes better with increasing Q value, where ω is a frequency of an electric signal passed through the signal line 41, C is the sum of a variable capacitance value in the MEMS capacitor and a parasitic capacitance between the MEMS capacitor and the semiconductor substrate, and R is an electric resistance of the signal line 41.

The reduction of the parasitic capacitance between the MEMS capacitor and the semiconductor substrate decreases C without reducing the variable capacitance value in the MEMS capacitor, which allows the Q value to be increased.

For example, the semiconductor substrate 1 is made of a Si-base crystal such as a Si crystal.

The insulating layer 2 is made of an insulating material such as SiO₂ and SiN. Alternatively, the insulating layer 2 may be formed by processing a Spin-On Glass (SOG) film. The air gap layers 2a, 2b, and 2c may be made of different materials.

The insulating film 3 is made of an insulating material such as SiO₂ and SiN.

The bridge 40, the signal line 41, the ground lines 42a and 42b, and the support portions 43a and 43b are made of a metallic material such as Al and Ni or an alloy material such as Al—Cu and Al—Si—Cu.

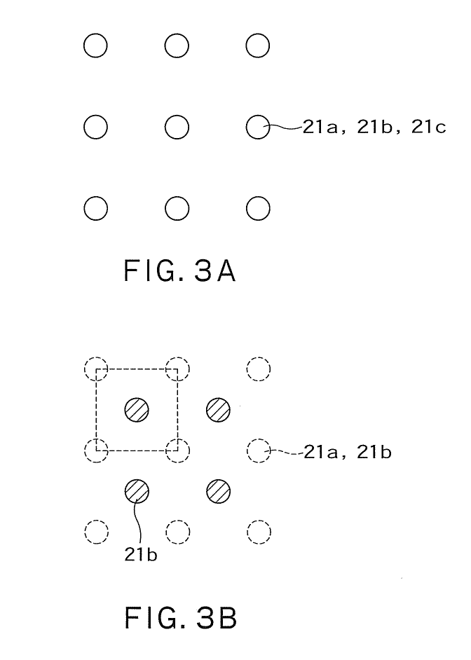

FIGS. 3A and 3B are top views schematically illustrating dispositions of the air gap groups 20a, 20b, and 20c when the air gap groups 20a, 20b, and 20c have quadrangular lattice (square lattice) patterns.

FIG. 3A is a top view illustrating a state in which the air gaps 21a, 21b, and 21c overlap one another when positions in the in-plane directions of the air gap groups 20a, 20b, and 20c are matched with one another. At this point, when the positions of the air gaps 21a, 21b, and 21c are taken into account as an atomic position in terms of a crystal structure, the air gaps 21a, 21b, and 21c have a structure close to a simple tetragonal structure.

FIG. 3B is a top view of the air gap groups 20a, 20b, and 20c when the positions in the in-plane direction of the air gap group 20b and air gap group 20a are different from each other. A lattice point of a quadrangular lattice pattern of the air gap group 20b is located immediately above the center between the lattices of the quadrangular lattice pattern of the air gap group 20a. The disposition of the air gap group 20c is matched with the position in the in-plane direction of the air gap group 20a. At this point, the air gaps 21a, 21b, and 21c have a structure close to a body-centered tetragonal structure. When at least three air gap layers are formed, a disposition (A) of the air gap group 20a and a disposition (B) of the air gap group 20b are alternately repeated (ABABAB . . . ).

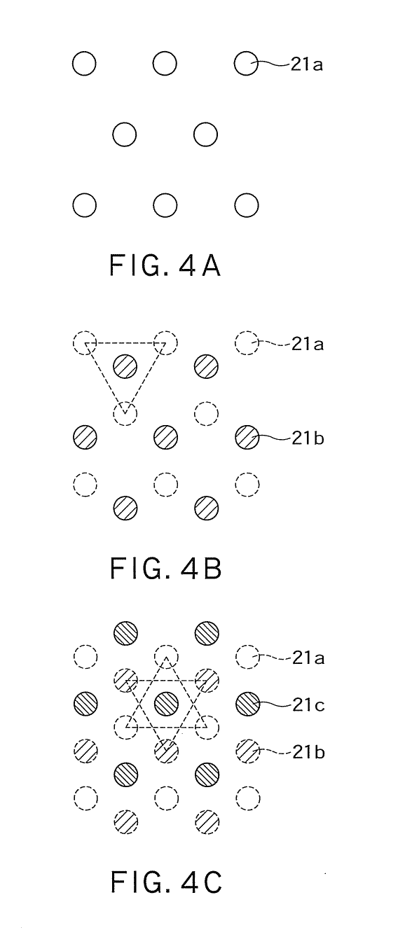

FIGS. 4A to 4C are top views schematically illustrating dispositions of the air gap groups 20a, 20b, and 20c when the air gap groups 20a, 20b, and 20c have triangular lattice (hexagonal lattice) patterns.

FIG. 4A is a top view illustrating the state in which the air gaps 21a, 21b, and 21c overlap one another when positions in the in-plane directions of the air gap groups 20a, 20b, and 20c are matched with one another. At this point, the air gaps 21a, 21b, and 21c have a structure close to a simple hexagonal structure.

FIG. 4B is a top view of the air gap groups 20a, 20b, and 20c when the disposition of the air gap group 20b deviates from the disposition of the air gap group 20a. A lattice point of a triangular lattice pattern of the air gap group 20b is located immediately above the center between the lattices of the triangular lattice pattern of the air gap group 20a. The positions in the in-plane directions of the air gap group 20c and air gap group 20a are matched with each other. At this point, the air gaps 21a, 21b, and 21c have a structure close to a hexagonal close-packed structure. When at least three air gap layers are formed, the disposition (A) of the air gap group 20a and the disposition (B) of the air gap group 20b are alternately repeated (ABABAB . . . ).

FIG. 4C is a top view of the air gap groups 20a, 20b, and 20c when the positions in the in-plane directions of the air gap groups 20a, 20b, and 20c are different from one another. The lattice point of the triangular lattice pattern of the air gap group 20b is located immediately above the center between the lattices of the triangular lattice pattern of the air gap group 20a. The lattice point of the triangular lattice pattern of the air gap group 20c is located immediately above the center between the lattices of the triangular lattice pattern of the air gap group 20a and immediately above the center between the lattices of the triangular lattice pattern of the air gap group 20b. At this point, the air gaps 21a, 21b, and 21c have a structure close to the hexagonal close-packed structure. When at least four air gap layers are formed, a disposition (A, B, C) of the air gap groups 20a, 20b, and 20c are alternately repeated (ABCABCABC . . . ).

When each of the air gap groups 20a, 20b, and 20c has a regular, periodic disposition as illustrated in FIGS. 3A, 3B and 4A to 4C, a variation in mechanical strength of each region of the insulating layer 2 is slightly, and a point at which the strength is extremely weak does not exist. Therefore, the decrease in mechanical strength of the insulating layer 2 can more effectively be suppressed.

As illustrated in FIGS. 3B, 4B and 4C, it can be expected that the mechanical strength of the insulating layer 2 is further enhanced by changing the positions in the in-plane directions of the air gap multi layer in each layer.

The air gap groups 20a, 20b, and 20c are not limited to the dispositions of FIGS. 3A, 3B and 4A to 4C. For example, the air gap groups 20a, 20b, and 20c may have different patterns. In the air gap groups 20a, 20b, and 20c, each of the air gaps 21a, 21b, and 21c may have a different shape and a different size.

An example of a method for manufacturing the MEMS element 100 of the embodiment will be described below.

### (Manufacturing of MEMS Element)

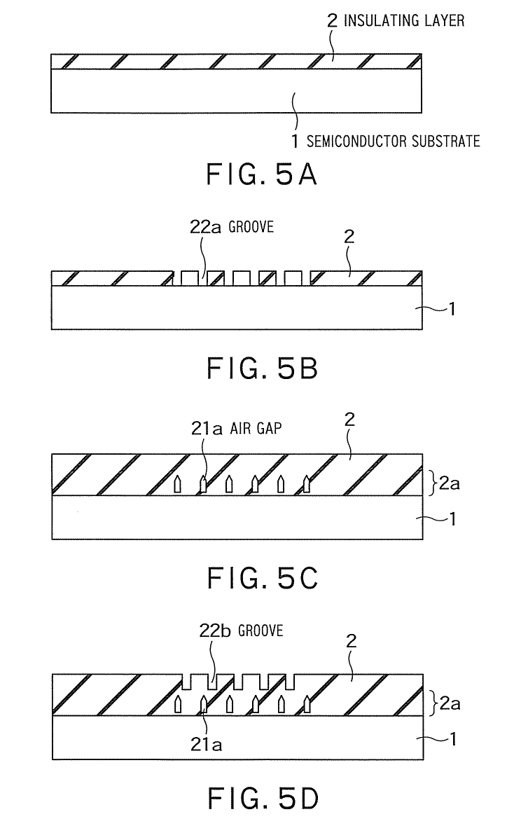

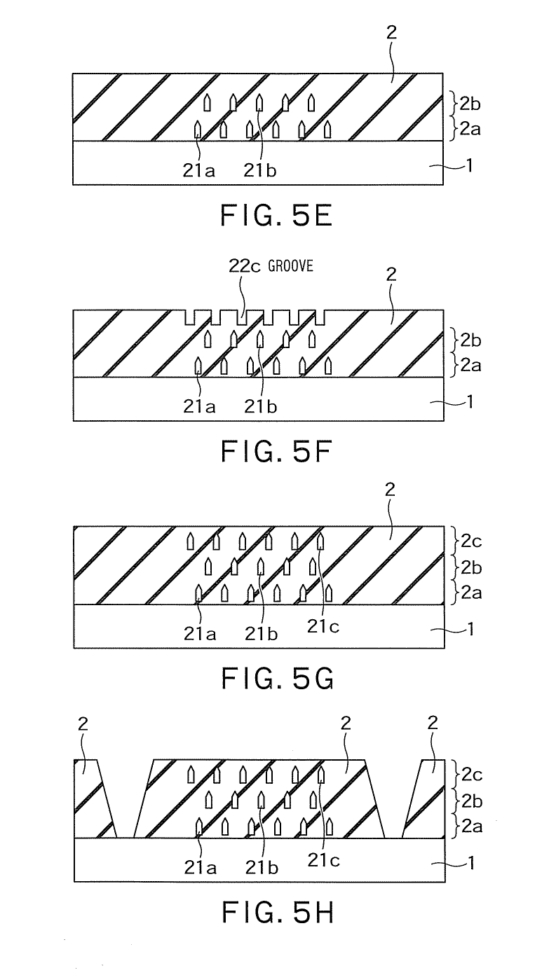

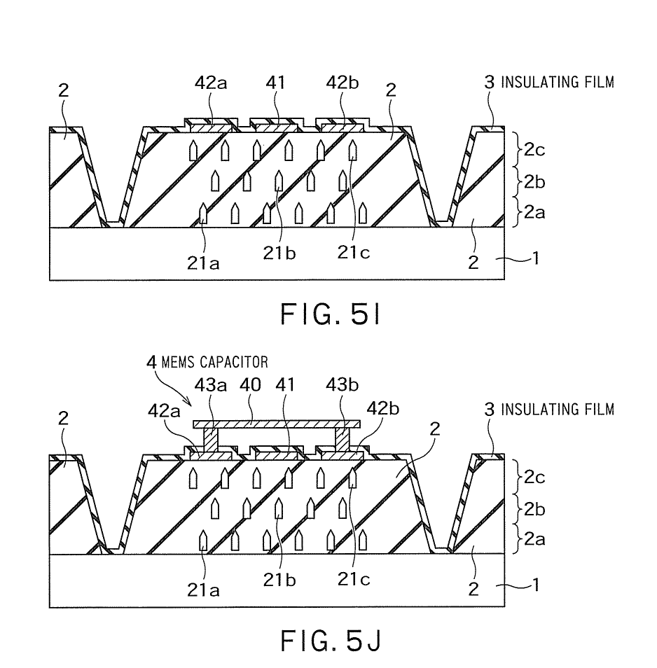

FIGS. 5A to 5J are sectional views illustrating the method for manufacturing the MEMS element 100 of the embodiment.

As illustrated in FIG. 5A, an insulating material is deposited on the semiconductor substrate 1 by a Chemical Vapor Deposition (CVD) method or the like to form the insulating layer 2 having a thickness of several micrometers to tens of micrometers.

As illustrated in FIG. 5B, the insulating layer 2 is patterned to form grooves 22a by a combination of a photolithographic method and a Reactive Ion Etching (RIE) method or the like.

The air gap layer 2a including the air gap 21a is formed as illustrated in FIG. 5C. The insulating material is deposited on the insulating layer 2 by the CVD method or the like such that the grooves 22a are not completely filled therewith, thereby increasing the thickness of the insulating layer 2. Then, an upper surface of the insulating layer 2 is planarized by Chemical Mechanical Polishing (CMP) or the like to obtain the air gap layer 2a.

As illustrated in FIG. 5D, the insulating layer 2 is patterned to form grooves 22b by the combination of the photolithographic method and the RIE method or the like. At this point, because there is a possibility that the air gap 21a and the groove 22b are connected with each other depending on the patterns of the air gap 21a and groove 22b, the groove 22b is formed such that the position of a bottom of the groove 22b preferably becomes higher than the position of an upper end of the air gap 21a.

The air gap layer 2b including the air gap 21b is formed as illustrated in FIG. 5E. The insulating material is deposited on the insulating layer 2 by the CVD method or the like such that the grooves 22b are not completely filled therewith, thereby increasing the thickness of the insulating layer 2. Then, the upper surface of the insulating layer 2 is planarized by CMP or the like to obtain the air gap layer 2b.

As illustrated in FIG. 5F, the insulating layer 2 is patterned to form grooves 22c by the combination of the photolithographic method and the RIE method or the like. At this point, the groove 22c is preferably formed such that the position of a bottom of the groove 22c becomes higher than the position of an upper end of the air gap 21b.

The air gap layer 2c including the air gap 21c is formed as illustrated in FIG. 5G. The insulating material is deposited on the insulating layer 2 by the CVD method or the like such that the grooves 22c are not completely filled therewith, thereby increasing the thickness of the insulating layer 2. Then, an upper surface of the insulating layer 2 is planarized by CMP or the like to obtain the air gap layer 2c.

As illustrated in FIG. 5H, the insulating layer 2 is patterned to process the insulating layer 2 into an island shape by the combination of the photolithographic method and the RIE method or the like.

The signal line 41, the ground lines 42a and 42b, and the insulating film 3 are formed as illustrated in FIG. 51. The signal line 41 and the ground lines 42a and 42b are formed by patterning the metallic film that is formed such that the insulating layer 2 is covered therewith.

The support portions 43a and 43b and the bridge 40 are formed as illustrated in FIG. 53. For example, the support portions 43a and 43b and the bridge 40 are formed in side faces and an upper surface of a sacrifice layer (not illustrated) formed on the insulating film 3, respectively. Then the sacrifice layer is removed.

According to the embodiment of the invention, the insulating layer 2 includes such air gap group as the air gap groups 20a, 20b, and 20c having the plural air gaps that are independently disposed in the in-plane direction, so that the decrease in mechanical strength of the insulating layer 2 can be suppressed compared with the formation of the one large air gap.

Compared with the formation of the vertically long air gap single layer, the decrease in mechanical strength can more effectively be suppressed by forming such air gap multi layer as the air gap layers 2a, 2b, and 2c. Because the air gaps can be formed in the wide range in the thickness direction of the insulating layer 2 without increasing the aspect ratio compared with the formation of the vertically long air gap single layer, the patterning of the insulating layer 2 is easily performed in order to form the air gap.

When each of the air gap groups 20a, 20b, and 20c has a regular, periodic disposition, the variation in mechanical strength of each region of the insulating layer 2 is suppressed, and the decrease in mechanical strength of the whole insulating layer 2 can more effectively be suppressed.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A MEMS element comprising:
a substrate;
an island insulating layer formed on the substrate, the insulating layer including an air gap layer having an air gap group, the air gap group including a plurality of air gaps disposed in an in-plane direction; and
a MEMS capacitor formed above the air gap group on the insulating layer.

2. The MEMS element according to claim 1, wherein a pattern of the air gap group is a quadrangular lattice pattern.

3. The MEMS element according to claim 1, wherein a pattern of the air gap group is a triangular lattice pattern.

4. The MEMS element according to claim 1, wherein the air gap layer is made of silicon oxide, silicon nitride or a SOG film.

5. The MEMS element according to claim 1, wherein the island insulating layer is covered with an insulating film.

6. The MEMS element according to claim 1, wherein the insulating layer includes:
a first air gap layer including a first air gap group; and
a second air gap layer including a second air gap group on the first air gap layer.

7. The MEMS element according to claim 6, wherein the first and second air gap groups have an identical pattern, and
the first and second air gap groups differ from each other in a position in an in-plane direction.

8. The MEMS element according to claim 7, wherein patterns of the first and second air gap groups are a quadrangular lattice pattern.

9. The MEMS element according to claim 8, wherein a lattice point of the pattern of the second air gap group is located immediately above a center between lattices of the pattern of the first air gap group.

10. The MEMS element according to claim 7, wherein patterns of the first and second air gap groups are a triangular lattice pattern.

11. The MEMS element according to claim 10, wherein a lattice point of the pattern of the second air gap group is located immediately above a center between lattices of the pattern of the first air gap group.

12. The MEMS element according to claim 1, wherein the insulating layer includes:
a first air gap layer including a first air gap group;
a second air gap layer including a second air gap group on the first air gap layer; and
a third air gap layer including a third air gap group on the second air gap layer.

13. The MEMS element according to claim 12, wherein the first, second, and third air gap groups have an identical pattern, the first air gap group differs from the second air gap group in a position in an in-plane direction, and
the first air gap group is identical to the third air gap group in the position in the in-plane direction.

14. The MEMS element according to claim 13, wherein patterns of the first, second, and third air gap groups are a quadrangular lattice pattern.

15. The MEMS element according to claim 14, wherein a lattice point of the pattern of the first air gap group overlaps a lattice point of the pattern of the third air gap group, and
a lattice point of the pattern of the second air gap group is located immediately above a center between lattices of the pattern of the first air gap group.

16. The MEMS element according to claim 13, wherein patterns of the first, second, and third air gap groups are a triangular lattice pattern.

17. The MEMS element according to claim 16, wherein a lattice point of the pattern of the first air gap group overlaps a lattice point of the pattern of the third air gap group, and
a lattice point of the pattern of the second air gap group is located immediately above a center between lattices of the pattern of the first air gap group.
